(19) United States
(12) Patent Application Publication
(10) Pub. No.: US 2009/0144968 A1
(43) Pub. Date: Jun. 11, 2009

(54) Pick-Up Tool And Method For Grasping And Mounting Small Dies

(75) Inventor: Rene Josef Ulrich, Weggis (CH)

Correspondence Address: Nixon Peabody LLP, 200 Page Mill Road, Palo Alto, CA, 94306, US

(73) Assignee: Oerlikon Assembly Equipment AG, Steinhausen, Cham (CH)

(21) Appl. No.: 12/263,084

(22) Filed: Oct. 31, 2008

Related U.S. Application Data
(60) Provisional application No. 61/002,585, filed on Nov. 8, 2007.

(30) Foreign Application Priority Data
Oct. 31, 2007 (CH) 1701/07

(51) Int. Cl. H01L 21/687; H05K 13/04; H01L 21/683

(52) U.S. Cl. 29/743; 29/740; 29/741; 29/742; 294/64.2

(57) ABSTRACT

A pick-up tool for gripping a die comprises a sleeve and a gripping member. The sleeve has a longitudinal bore extending in the longitudinal direction in which the gripping member is inserted. The gripping member is held in the sleeve displaceably in the longitudinal direction. A portion of the gripping member protrudes from the sleeve. The gripping member assumes a predetermined position relative to the sleeve at the absence of any external action of force on the portion of the gripping member protruding from the sleeve, in which the portion of the gripping member protruding from the sleeve is held in a play-free manner radially to the longitudinal direction. In the case of action of force in the longitudinal direction on the portion of the gripping member protruding from the sleeve, the gripping member can be inserted further into the sleeve and is then radially movably held in the longitudinal bore of the sleeve. The mass of the gripping member is not more than 1 gram.

### PRIORITY CLAIM

Applicant hereby claims foreign priority under 35 U.S.C § 119 from Swiss patent application no. 1701/07 filed Oct. 31, 2007 and from U.S. provisional patent application No. 61/002,585 filed Nov. 8, 2007, the disclosures of which are herein incorporated by reference.

### FIELD OF THE INVENTION

The invention relates to a pick-up tool and a method for grasping and mounting small dies. The term “die” is used in the field as a synonym for a bare semiconductor chip.

### BACKGROUND OF THE INVENTION

During the mounting of dies, the dies which are sawed out of a wafer and adhere to a film are grasped by a pick-up tool and placed on a substrate. Such a pick-up tool substantially consists of a metal shaft and a gripping member which is fastened thereto and comprises a suction opening to which vacuum can be applied. Once the gripping member rests on the die, the vacuum causes the adherence of the die to the gripping member.

In order to avoid even the smallest injuries of the die during mounting, pick-up tools are used whenever possible whose gripping member consists of rubber. Rubber comes with the additional advantage that it seals the suction opening very well. Gripping members made of rubber cannot be used for the mounting of small dies because they cannot be produced with the necessary precision. “Small dies” are understood to be semiconductor chips whose side length is in the range of merely 0.1 mm to approximately 1.2 mm. Gripping members made of plastic, preferably of Vespel, are used for mounting small dies.

Mounting occurs by means of mounting machines which are known in the field as die bonders. A die bonder comprises a pick-and-place system which moves a bonding head with a chip gripper between the wafer table and the substrate back and forth. The pick-up tool is fastened to the chip gripper. The chip gripper bears pneumatically or by means of a spring on the bonding head, so that the chip gripper will deflect during the taking of the die from the wafer table and during the bonding of the die on the substrate.

Very high demands are placed on mounting. On the one hand, a very high placement precision of the dies on the substrate is required. In order to achieve this, the gripping member is rigidly fastened to the chip gripper. On the other hand, a throughput of the mounting machine as high as possible is required, which means that the pick-up tool must be moved with high speed from the wafer table to the substrate and back again. Although the peak-up tool is strongly braked for receiving the die from the wafer table and although the chip gripper deflects upon touching the die, the pick-up tool will impinge upon the die. Considerably forces occur here which lead to various undesirable effects:
There are always dies which are damaged upon impingement of the pick-up tool.
The gripping member wears off relatively fast because it is deformed by the very high number of impingements on the dies.

### SUMMARY OF THE INVENTION

The invention is based on the object of enabling the mounting of small dies with high placement precision and high throughput of the mounting machine without giving rise to the above problems.

A pick-up tool for grasping a die comprises according to the invention a sleeve comprising an outlet opening and a longitudinal bore extending in a longitudinal direction and communicating with the outlet opening, and a gripping member inserted in the sleeve, the gripping member bearing in the sleeve displaceably in the longitudinal direction and having a portion protruding from the sleeve, wherein, at the absence of an external force acting on the portion of the gripping member protruding from the sleeve, the gripping member assumes a predetermined position relative to the sleeve in which the portion of the gripping member protruding from the sleeve is held radially to the longitudinal direction in a play-free manner at least in the region of the outlet opening of the sleeve, and wherein, in the case of a force acting in the longitudinal direction on the portion of the gripping member protruding from the sleeve, the gripping member is further insertable in the sleeve and then bears movably radially to the longitudinal direction in the longitudinal bore of the sleeve.

Preferably, the gripping member is oblong and an inside diameter of the longitudinal bore of the sleeve is larger than a largest outside diameter of the gripping member and the sleeve comprises an outlet opening whose diameter is smaller than a largest outside diameter of the gripping member and at least a part of the portion of the gripping member protruding from the sleeve has a smaller outside diameter than the outlet opening of the sleeve.

Preferably, a means presses the gripping member against the outlet opening, said means comprising for example a spring or a magnet or a fluid cushion. The gripping member typically is a suction member.

### BRIEF DESCRIPTION OF THE DRAWING FIGURES

The accompanying drawings, which are incorporated into and constitute a part of this specification, illustrate one or more embodiments of the present invention and, together with the detailed description, serve to explain the principles and implementations of the invention. The figures are not to scale. In the drawings:

FIG. 1 shows schematically a side view of a bonding head with a chip gripper with a pick-up tool in accordance with the invention;

FIG. 2 shows the pick-up tool in a sectional view;

FIG. 3 shows a sectional view of FIG. 2 in an enlarged view;

FIGS. 4, 5 illustrate a first aspect of the invention, and

FIGS. 6, 7 show further pick-up tools in a sectional view.

### DETAILED DESCRIPTION OF THE INVENTION

The invention is explained by reference to a pick-up tool for mounting the dies by means of a die bonder. The die bonder comprises a pick-and-place system which moves a bonding head between the wafer table and the substrate back and forth. A chip gripper is held in a displaceable manner relative to the bonding head in a pneumatic manner or by means of a spring, so that the chip gripper will deflect when taking dies from the wafer table and during bonding of the die on the substrate. The pick-up tool is fastened to the chip gripper.

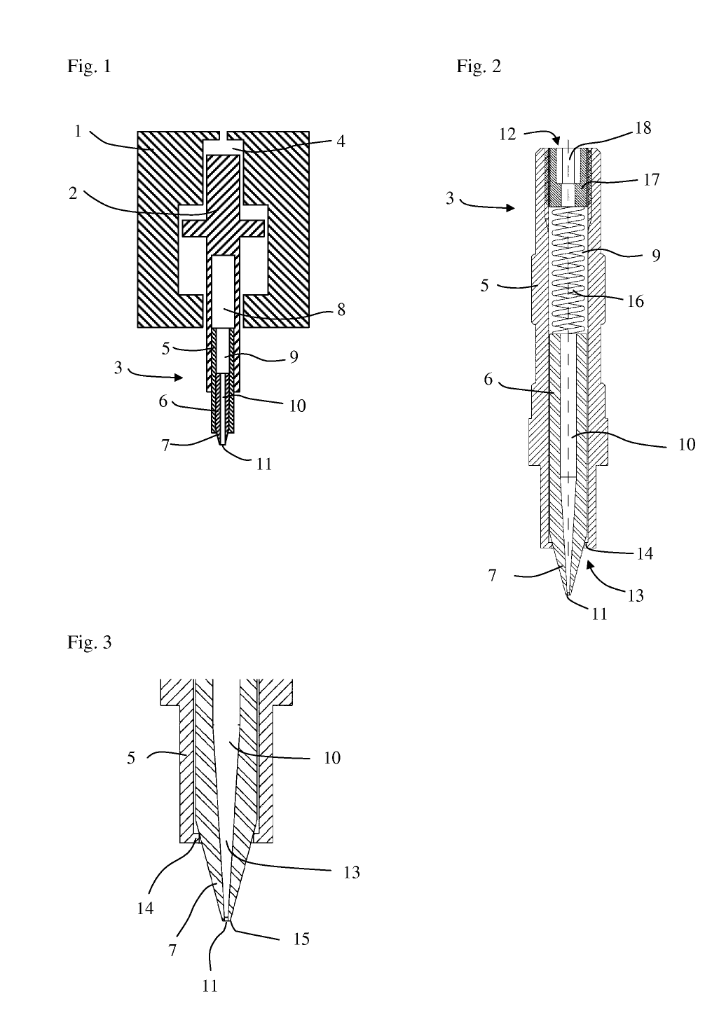

FIG. 1 schematically shows a lateral view of the bonding head 1 and the chip gripper 2 with the pick-up tool 3 in accordance with the invention. Parts of the bonding head 1 which are not necessary for the understanding of the invention are not shown. In this example, the chip gripper 2 is held pneumatically in a pressure chamber 4 attached in the bonding head 1. The chip gripper 2 can also bear in a different manner in the bonding head 1, e.g. pretensioned by means of a spring. The pick-up tool 3 comprises a sleeve 5 with a longitudinal bore 9 extending in a longitudinal direction and communicating with an outlet opening 13 of the sleeve 5, in which bore a gripping member 6 is inserted. The gripping member 6 is displaceably held in the longitudinal direction of longitudinal bore 9 and is held in a resilient manner in sleeve 5 in the longitudinal direction. Resiliently held in the longitudinal direction shall mean within the scope of the invention that means are provided which push back the gripping member 6 to its initial position after the displacement of the same in the longitudinal direction has been completed. The gripping member 6 has a portion which protrudes from the sleeve 5 and is formed with a tip 7. The portion of the gripping member 6 which protrudes from the sleeve 5 tapers continuously in this example. The continuous tapering is merely necessary in the area of the outlet opening 13 of the sleeve 5 in order to ensure that in the case of an even merely small displacement of the gripping member 6 into the sleeve 5 the gripping member 6 is movable radially to the longitudinal axis. The continuous tapering can be arranged at will. Preferably, however, a spherical tapering and more preferably a conical tapering will be realized.

The chip gripper 2 according to FIG. 1 comprises a longitudinal bore 8 which receives the pick-up tool 3. The sleeve 5 is detachably fastened to chip gripper 2. The gripping member 6 is preferably a suction member which is typically based on the suction principle or the Bernoulli effect. Within the scope of the suction principle, a negative pressure (or vacuum) is generated in the sleeve 5, and within the scope of the Bernoulli effect air or gas flows out from the gripping member 6 to produce a suction force. Within the scope of the Bernoulli effect, the gripping member 6 is supplied with compressed air or a gas in order to build up an air or gas flow in the direction towards the die to be gripped. The gripping member 6 can be configured in such a way that the die can be gripped in a contactless manner. The gripping member 6 has a longitudinal bore 10 which opens at the front of the tip 7 into an opening 11 which in the present case in which the gripping member 6 is based on the suction principle is a suction opening. The three longitudinal bores 8, 9 and 10 lie on a common longitudinal axis and are connected with each other in respect of pressure, so that a negative pressure or overpressure applied to the longitudinal bore 8 of chip gripper 2 is also applied to the opening 11 of the gripping member 6.

Details of the gripping member 6 are now explained by reference to FIG. 2 which shows the pick-up tool 3 in a sectional view. The longitudinal bore 9 of the sleeve 5 has an inlet opening 12 and an outlet opening 13. The sleeve 5 has a projection 14 protruding into the longitudinal bore 9 at its end facing the tip 7 of the gripping member 6, which projection reduces the diameter of the longitudinal bore 9 in the outlet opening 13: the diameter of the outlet opening 13 of the sleeve 5 is thus smaller than the diameter of the inlet opening 12 of the sleeve 5. The largest outside diameter of the portion of the gripping member 6 which is guided in the sleeve 5 is larger than the diameter of the outlet opening 13 of the sleeve 5 and is smaller than the inside diameter of the longitudinal bore 9 of the sleeve 5. The gripping member 6 is introduced into the sleeve 5 through the inlet opening 12 of the sleeve 5. The projection 14 of the sleeve 5 prevents that the gripping member 6 can fall out of the outlet opening 13.

FIG. 3 shows a section of FIG. 2 with the tip 7 on an enlarged scale, in which the projection 14 is clearly visible. The surface 15 which encloses the outlet opening 13 is planar and ideally extends planar to the surface of the die to be received. In a typical example, the inside diameter of the longitudinal bore 9 of the sleeve 5 is 1.60 mm, the outside diameter of the gripping member 6 is 1.58 mm and the diameter of the outlet opening 13 is 1.40 mm. To ensure that the opening 11 of tip 7 of the gripping member 6 always assumes the same position despite the play of 0.02 mm, the gripping member 6 is guided in the longitudinal bore 9 of the sleeve 5 over a length which is at least three times as large as the maximum outside diameter of the gripping member 6. The difference between the outside diameter of the gripping member 6 and the inside diameter of the longitudinal bore 9 of sleeve 5 can also be more than 0.02 mm, typically up to 0.05 mm, in the case of a respective length of the gripping member 6.

The resilient bearing of the gripping member 6 in the sleeve 5 is caused in the embodiment as shown in FIG. 2 by a spring 16 which is clamped between the gripping member 6 and a screw 17 screwed into the longitudinal bore 9 of the sleeve 5. The longitudinal bore 9 of the sleeve 5 is provided with a matching thread for this purpose. The screw 17 comprises a central bore 18, so that the vacuum applied to the chip gripper 2 can reach up to the opening 11 of the gripping member 6. The spring 16 is pretensioned, so that it will press with a predetermined force against the gripping member 6. This force must be larger than the force exerted during the application of vacuum on the gripping member 6, so that the spring 16 will press the tip 7 of the gripping member 6 in any case as far as mechanically possible out of the sleeve 5.

The spring constant of the spring 16 typically lies in the range of 500 mN/mm to 1 N/mm. The pretensioning force of the spring 16 is approximately 750 mN in the example. The force exerted on the gripping member 6 is reduced by the applied suction vacuum by approximately 150 mN, so that the effective force is merely 600 mN. The distance by which the tip 7 of the gripping member 6 is pressed into the sleeve 5 during the impingement on the die is 0.7 mm as a maximum in the example. The force exerted as a maximum by the gripping member 6 on the die is calculated as force=pretensioning force−suction vacuum+(spring constant*maximum deflection path) and therefore reaches approximately 950 mN as a maximum at a spring constant of 500 mN/mm.

Especially in the case of the smallest of the small dies, the gripping member 6 is preferably a capillary made of ceramic, since ceramic is a very hard material which is capable of withstanding the forces occurring during the impingement of the gripping member 6 on the die longer than other materials. The sleeve 5 is preferably made of stainless steel, so that it does not corrode. This pairing of materials, stainless steel for the sleeve 5 and ceramic for the gripping member 6, offers the further advantage that no lubricant or anti-blocking agent is required.

In the case of slightly larger dies, the gripping member 6 can also be made of Vespel, which occurs in cases when the surface 15 which encloses the opening 11 can already be formed in a sufficiently large way so that it is able to sufficiently withstand the occurring forces without being deformed and worn off too quickly as a result of excessive surface loading.

These gripping members 6 made of ceramic or Vespel can be used in different mounting methods, which include bonding with an epoxy adhesive, eutectic soldering or so-called soft soldering in which the substrate is heated to a temperature up to 450° Celsius.

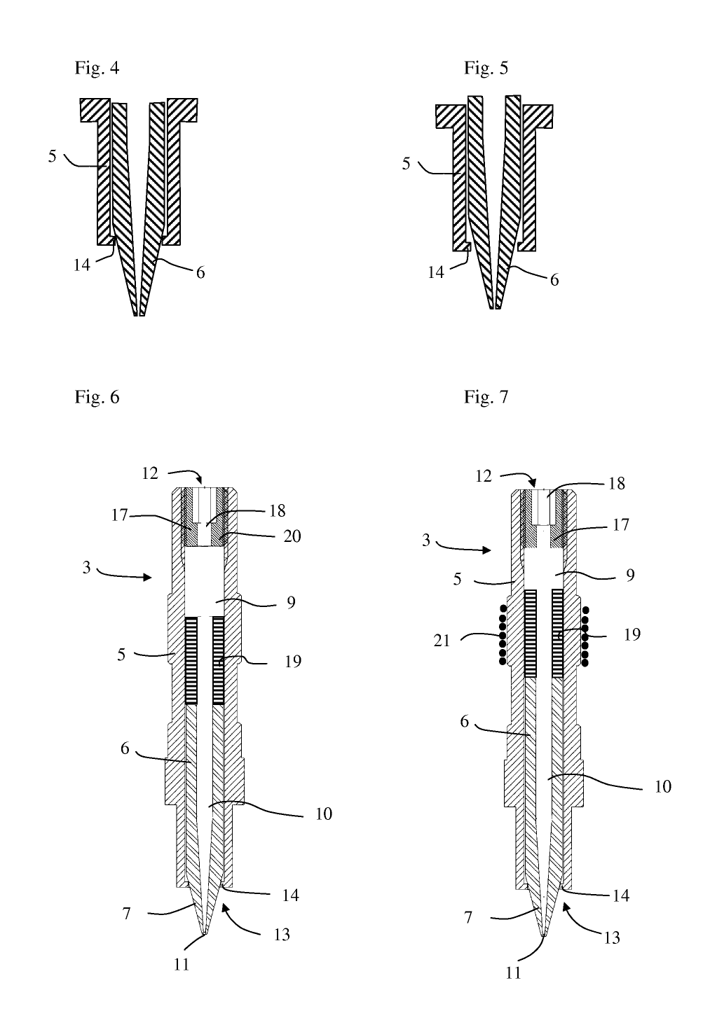

The pick-up tool 3 in accordance with the invention is based on two aspects, of which at least one, but preferably both, need to be realized for achieving the object. The first aspect is to uncouple the gripping member 6 mechanically from the sleeve 5 once the gripping member 6 has touched the die to be picked up and is slightly pressed into the sleeve 5 as a result of the force acting thereby without reducing the placement precision. The present construction ensures this as follows: At the absence of any external action of force on the portion of the gripping member 6 protruding from the sleeve 5, the spring 16 presses the gripping member 6 in the longitudinal direction of the longitudinal bore 9 against the projection 14, so that the portion of the gripping member 6 which protrudes from the sleeve 5 assumes a predetermined position relative to the sleeve 5 in which the portion of the gripping member 6 protruding from the sleeve 5 is held in a play-free manner radially to the longitudinal direction at least in the outlet region of the sleeve 5. Since the gripping member 6 is pressed by the spring 16 against the projection 14 of the sleeve 5, the gripping member 6 cannot move in this region in the radial direction (i.e. in any random direction extending transversally to the longitudinal direction). This state is shown in FIG. 4. Once on the action of an external force on the portion of the gripping member 6 protruding from the sleeve 5, e.g. by interaction with a die to be gripped, the gripping member 6 is pressed slightly into the sleeve 5, the contact on all sides between the conically tapering tip 7 of the gripping member 6 and the projection 14 of the sleeve 5 is lost. The gripping member 6 is now radially movable. This state is shown in FIG. 5. The gap existing between the gripping member 6 and the sleeve 5 is at least 10 μm in this example. It can also be larger however and be up to 25 μm or possibly even more. This gap is large enough on the one hand, so that vibrations of the bonding head 1 (FIG. 1) which occur during strong braking of the bonding head 1 are not transmitted to the gripping member 6. The gap is large enough on the other hand that the inert mass of the gripping member 6 which acts during the impingement on the die is not increased by frictional forces.

The second aspect is to markedly reduce the mass which acts upon the die during the impingement of the gripping member 6 as compared with the state of the art. This is achieved in such a way that the weight of the gripping member 6 with typically only 0.015 g (grams) or also up to 0.05 g is very low, so that the impulse that is exerted by the inertial mass of the gripping member 6 upon impingement on the die is virtually meaningless. The force acting at a maximum on the die therefore only corresponds to the force which the spring 16 exerts on the gripping member 6 after the impingement of the gripping member 6 on the die once the gripping member 6 has been pressed into the sleeve 5. When the friction between the gripping member 6 and the sleeve 5 is sufficiently small, the mass of the gripping member 6 can be up to 1 g. This is still one order of magnitude smaller than is the case in chip grippers according to the state of the art where the mass is more than 10 g, which generates a very large impulse during impingement. Due to this aspect to the invention, the mass of the chip gripper does not contribute to the force which acts on the die during impingement.

The resilient bearing of the gripping member 6 in the sleeve 5 can also be achieved in a manner other than illustrated above, e.g. in a magnetic way for example. One example of a magnetic solution is shown in FIG. 6. Instead of the spring, two magnets 19 and 20 are present, of which the one magnet 19 is fastened to the end of the gripping member 6 and the other magnet 20 is arranged as a screw with a central bore 18, like the screw as shown in FIG. 2, and is screwed into the longitudinal bore 9 of the sleeve 5. The two mutually facing poles of the magnets 19 and 20 are the same poles, namely either both north poles or both south poles, so that the two magnets 19 and 20 will repel each other.

An example of a further magnetic solution is shown in FIG. 7. Instead of the spring 16, a magnet 19 or a body made of ferromagnetic material is fastened to the end of the gripping member 6 and a coil is wound around the sleeve 5. In order to exert a force on the gripping member 6, the coil 21 is supplied with a direct current. This solution allows controlling the force, since the force is proportional to the strength of the current. The screw 17 is used in this case for securing the gripping member 6 against falling out.

The resilient bearing of the gripping member 6 in the sleeve 5 can further be realized by a fluid cushion, by electric forces or light forces.

The pick-up tool 3 in accordance with the invention is especially suitable for mounting dies. The sleeve 5 of the pick-up tool 3 is fastened for this purpose to chip gripper 2. The gripping of the die occurs with the following steps:
approximating the pick-up tool in a predetermined direction towards the die to be gripped until the gripping member 6 of the pick-up tool 3 touches the die 10, and
approximating the pick-up tool 3 further until the gripping member 6 is held movably radially to the predetermined direction.
   The mounting of the die occurs with the following steps:
grasping the die to be mounted as described above;
transporting the die to the position determined for mounting, and
placing the die.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims and their equivalents.

What is claimed is:

1. A pick-up tool for grasping a die, comprising
a sleeve comprising an outlet opening and a longitudinal bore extending in a longitudinal direction and communicating with the outlet opening, and
a gripping member inserted in the sleeve, the gripping member bearing in the sleeve displaceably in the longitudinal direction and having a portion protruding from the sleeve, wherein, at the absence of an external force acting on the portion of the gripping member protruding from the sleeve, the gripping member assumes a predetermined position relative to the sleeve in which the portion of the gripping member protruding from the sleeve is held radially to the longitudinal direction in a play-free manner at least in the region of the outlet opening of the sleeve, and wherein, in the case of a force acting in the longitudinal direction on the portion of the gripping member protruding from the sleeve, the gripping member is further insertable in the sleeve and then bears movably radially to the longitudinal direction in the longitudinal bore of the sleeve.

2. A pick-up tool according to claim 1, wherein the mass of the gripping member is not more than 1 gram.

3. A pick-up tool according to claim 1, wherein the gripping member is oblong, wherein an inside diameter of the longitudinal bore of the sleeve is larger than a largest outside diameter of the gripping member, wherein the sleeve comprises an outlet opening whose diameter is smaller than a largest outside diameter of the gripping member and wherein at least a part of the portion of the gripping member protruding from the sleeve has a smaller outside diameter than the outlet opening of the sleeve.

4. A pick-up tool according to claim 2, wherein the gripping member is oblong, wherein an inside diameter of the longitudinal bore of the sleeve is larger than a largest outside diameter of the gripping member, wherein the sleeve comprises an outlet opening whose diameter is smaller than a largest outside diameter of the gripping member and wherein at least a part of the portion of the gripping member protruding from the sleeve has a smaller outside diameter than the outlet opening of the sleeve.

5. A pick-up tool according to claim 1, wherein the portion of the gripping member protruding from the sleeve tapers continuously at least in the region of the outlet opening of the sleeve.

6. A pick-up tool according to claim 3, wherein the portion of the gripping member protruding from the sleeve tapers continuously at least in the region of the outlet opening of the sleeve.

7. A pick-up tool according to claim 1, wherein the gripping member is a capillary made of ceramic.

8. A pick-up tool according to claim 5, wherein the sleeve is made of stainless steel.

9. A pick-up tool according to claim 1, wherein a means presses the gripping member against the outlet opening.

10. A pick-up tool according to claim 9, wherein said means comprises a spring or a magnet or a fluid cushion.

11. A pick-up tool according to claim 3, wherein a means presses the gripping member against the outlet opening.

12. A pick-up tool according to claim 11, wherein said means comprises a spring or a magnet or a fluid cushion.

13. A pick-up tool according to claim 1, wherein the gripping member is a suction member.

14. A pick-up tool according to claim 3, wherein the gripping member is a suction member.

15. A pick-up tool according to claim 10, wherein the gripping member is a suction member.

16. A pick-up tool according to claim 1, wherein the gripping member is guided in the longitudinal bore of the sleeve over a length which is at least three times as large as the largest outside diameter of the portion of the gripping member guided in the sleeve.

17. A pick-up tool according to claim 3, wherein the gripping member is guided in the longitudinal bore of the sleeve over a length which is at least three times as large as the largest outside diameter of the portion of the gripping member guided in the sleeve.

18. A pick-up tool according to claim 4, wherein the gripping member is guided in the longitudinal bore of the sleeve over a length which is at least three times as large as the largest outside diameter of the portion of the gripping member guided in the sleeve.

19. A method for grasping a die, comprising
approximating a pick-up tool according to claim 1 in a predetermined direction towards the die to be gripped until the gripping member of the pick-up tool touches said die, and
approximating the pick-up tool further until the gripping member is held movably radially to the predetermined direction.

20. A method according to claim 19, further comprising
transporting the die to a position determined for mounting, and
placing the die on a substrate.
